(19) United States
(12) Patent Application Publication
(10) Pub. No.: US 2024/0200168 A1
(43) Pub. Date: Jun. 20, 2024

(54) COPPER ALLOY MATERIAL AND SHUNT RESISTOR

(71) Applicant: KOA CORPORATION, Ina-shi (JP)

(72) Inventors: Yoshitaka KUMEDA, Nagano (JP); Tadahiko Yoshioka, Nagano (JP)

(21) Appl. No.: 18/529,604

(22) Filed: Dec. 5, 2023

(30) Foreign Application Priority Data
Dec. 19, 2022 (JP) 2022-202094

(51) Int. Cl. C22C 9/05; G01R 1/20

(52) U.S. Cl. CPC C22C 9/05; G01R 1/203

(57) ABSTRACT

A copper alloy material having a low volume resistivity, a low TCR and a small thermal electromotive force with respect to copper and a shunt resistor comprising a resistive body formed by the copper alloy material are provided. The copper-manganese-based copper alloy material includes 4.5-5.5 mass % of manganese, 0.1-0.3 mass % of iron, 0.1-0.5 mass % of tin, and a balance being copper. A volume resistivity is 15-25 μΩ·cm. An absolute value of TCR is 150×10⁻⁶/K or less. A thermal electromotive force with respect to copper is 1 μV/K or less. A resistance value change is −0.3% to 0% in a heat resistance test of 175° C. for 3000 hours.

### RELATED APPLICATIONS

The present application claims priority from Japanese patent application JP2022-202094 filed on Dec. 19, 2022, the entire content of which is hereby incorporated by reference into this application.

### BACKGROUND OF THE INVENTION

### Field of the Invention

The present invention relates to a copper alloy material and a shunt resistor.

### Description of the Related Art

Major resistance alloys used in a shunt resistor include copper-manganese-based alloys (Manganin®): copper-manganese-nickel), copper-nickel-based alloys, nickel-chromium-based alloys and iron-chromium-based alloys. In many cases of resistance alloy for shunt resistors, a copper-manganese-based alloy, which has a small absolute value of TCR (Temperature Coefficient of Resistance) and a small absolute value of thermal electromotive force with respect to copper, is used in order to obtain high current detection accuracy.

With conventional copper alloy materials, it is difficult to construct a resistance alloy having a low volume resistivity (for example, about 20 μΩ·cm or less, or 15-25 μΩ·cm), a low TCR (for example, 100×10⁻⁶/K or less, or 150×10⁻⁶/K or less) and a small thermal electromotive force with respect to copper (for example, 1 μV/K or less).

As a copper-manganese-based alloy, there is a copper-manganese-tin-based alloy having a volume resistivity of about 29 μΩ·cm. In order to design a small shunt resistor using this resistance alloy, a plate thickness of a resistive body must be thick in order to reduce resistance, which makes press working difficult. On the other hand, if the resistance is reduced by decreasing a distance between electrodes, contribution of the TCR of the electrodes consisting of copper would be greater, so the TCR of the shunt resistor as an entire product would increase.

It is considered to use a copper-nickel-based alloy having a low volume resistivity (about 20 μΩ·cm of volume resistivity) for a resistive material of the shunt resistor. However, the TCR of this resistance alloy is generally large, so the TCR of a product would also be large. Further, the thermal electromotive force with respect to copper is also large, which is not suitable for a resistance alloy for a shunt resistor.

JP2022-040517 A discloses a resistance alloy having an improved thermal electromotive force with respect to copper by adding iron and silicon to a copper-manganese-based metal. However, further property improvement is desired.

Note that electrical performance in a heat resistance test is worsened by adding iron for the purpose of reducing the thermal electromotive force with respect to copper. It is preferable to reduce the TCR while preventing this performance degradation.

The present invention is made in order to solve the foregoing problems, and an object thereof is to provide a copper alloy material having a low volume resistivity (for example, about 20 μΩ·cm or less, or 15-25 μΩ·cm), a low TCR (for example, 100×10⁻⁶/K or less, or 150×10⁻⁶/K or less) and a small thermal electromotive force with respect to copper (for example, 1 μV/K or less), and a shunt resistor comprising a resistive body formed by the copper alloy material.

### SUMMARY OF THE INVENTION

An example of a copper-manganese-based copper alloy material related to the present invention includes 4.5-5.5 mass % of manganese, 0.1-0.3 mass % of iron, 0.1-0.5 mass % of tin, and a balance being copper.

In an example, a volume resistivity is 15-25 μΩ· cm.

In an example, an absolute value of TCR is 150×10⁻⁶/K or less.

In an example, a thermal electromotive force with respect to copper is 1 μV/K or less.

In an example, a resistance value change is −0.3% to 0% in a heat resistance test of 175° C. for 3000 hours.

An example of a shunt resistor related to the present invention is a shunt resistor for current detection comprising a resistive body and an electrode, wherein: the resistive body is formed by a copper-manganese-based copper alloy material; and the copper alloy material includes 4.5-5.5 mass % of manganese, 0.1-0.3 mass % of iron, 0.1-0.5 mass % of tin, and a balance being copper.

According to a copper alloy material and a shunt resistor related to the present invention, a low volume resistivity (for example, about 20 μΩ·cm or less, or 15-25 μΩ·cm), a low TCR (for example, 100×10⁻⁶/K or less, or 150×10⁻⁶/K or less) and a small thermal electromotive force with respect to copper (for example, 1 μV/K or less) are realized.

### BRIEF DESCRIPTION OF THE DRAWINGS

FIG. 1 is a phase diagram of a copper alloy material related to a first embodiment;

FIG. 2 is a graph showing relationship between volume resistivity and TCR for Samples 1-4 and 9-14;

FIG. 3 is a graph showing relationship between content of iron and resistance value change for Samples 2 and 5-8;

FIG. 4 is a graph showing relationship between content of tin and resistance value change for Samples 2 and 9-14;

FIG. 5 is a graph showing relationship between content of tin and resistance value change for Samples 6 and Examples 1-3; and

FIGS. 6A, 6B and 6C show an exemplary construction of a shunt resistor related to a second embodiment.

### DETAILED DESCRIPTION OF THE PREFERRED EMBODIMENTS

Embodiments of the present invention will be described below based on the attached drawings.

### First Embodiment

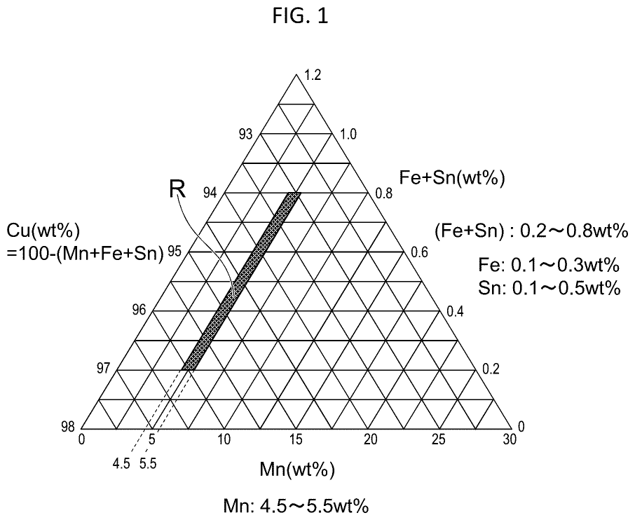

FIG. 1 is a phase diagram of a copper alloy material related to a first embodiment. The copper alloy material includes manganese, iron and tin beside copper. Mass fraction of copper is indicated on the top-left axis, a sum of mass fractions of iron and tin is indicated on the top-right axis and mass fraction of manganese is indicated on the bottom axis.

FIG. 1 shows a region R characterizing the copper alloy material in accordance with the present embodiment. A mass fraction of manganese in the region R is 4.5% to 5.5%. A sum of mass fractions of iron and tin in the region R is 0.2% to 0.8%, and in more detail, a mass fraction of iron is 0.1% to 0.3% and a mass fraction of tin is from 0.1% to 0.5%. A balance is copper.

As shown in Table 1 below, properties were measured for each of copper-manganese-based copper alloy materials having various compositions. Specifically, the table shows compositions and properties of Examples 1-3 in the present embodiment, Samples 1-14 for verifying composition ranges, and Comparative Examples 1-2.

TABLE 1

| | | | | | | | TCR | Resistance | Thermal |
|---|---|---|---|---|---|---|---|---|---|
| | | | | | | Volume | (100° C./ | value change | electromotive |
| | Composition (mass %) | | | | | resistivity | 25° C.) | (175° C., | force to copper |
| | Cu | Mn | Fe | Sn | Si | (μΩ · cm) | (×10⁻⁶/K) | 3000 Hr)(%) | (0~100° C.)(μV/K) |
| Example 1 | Bal. | 5 | 0.2 | 0.1 | — | 20 | 81 | −0.24 | 0.31 |
| Example 2 | Bal. | 5 | 0.2 | 0.3 | — | 20.5 | 75 | −0.25 | 0.25 |
| Example 3 | Bal. | 5 | 0.2 | 0.5 | — | 21 | 69 | −0.27 | 0.16 |
| Sample 1 | Bal. | 4.5 | — | — | — | 17.2 | 132 | −0.45 | 0.87 |
| Sample 2 | Bal. | 5 | — | — | — | 18.9 | 99 | −0.52 | 0.95 |
| Sample 3 | Bal. | 5.5 | — | — | — | 20.7 | 76 | −0.84 | 1.04 |
| Sample 4 | Bal. | 7 | — | — | — | 24.5 | 26 | — | 1.25 |
| Sample 5 | Bal. | 5 | 0.1 | — | — | 19.6 | 93 | −0.56 | 0.22 |
| Sample 6 | Bal. | 5 | 0.2 | — | — | 20.1 | 89 | −1.02 | −0.32 |
| Sample 7 | Bal. | 5 | 0.5 | — | — | 20.9 | 76 | −1.16 | — |
| Sample 8 | Bal. | 5 | 1 | — | — | 21.2 | 82 | −1.21 | — |
| Sample 9 | Bal. | 5 | — | 0.1 | — | 18.5 | 101 | −0.09 | 1.15 |
| Sample 10 | Bal. | 5 | — | 0.2 | — | 18.7 | 95 | 0.01 | 1.12 |
| Sample 11 | Bal. | 5 | — | 0.5 | — | 19.4 | 86 | −0.09 | 1.06 |
| Sample 12 | Bal. | 5 | — | 1 | — | 20.5 | 73 | −0.22 | 0.78 |
| Sample 13 | Bal. | 5 | — | 2 | — | 22.3 | 58 | −0.2 | 0.44 |
| Sample 14 | Bal. | 5 | — | 3 | — | 24.1 | 53 | −0.2 | 0.21 |
| Comparative | Bal. | 5 | 0.2 | — | 0.1 | 20 | 84 | −1.21 | 0.11 |
| Example 1 | | | | | | | | | |
| Comparative | Bal. | 5 | 0.2 | — | 0.2 | 20.8 | 77 | −1.19 | 0.09 |
| Example 2 | | | | | | | | | |

Note that, as a condition in heat resistance tests (except Sample 4), thicknesses of the material were set to 400-500 μm, temperatures were maintained at 175° C. for 3000 hours in the atmosphere and then resistance value changes were measured.

Comparing Samples 1-4, addition of manganese raises the volume resistivity while reduces TCR (Temperature Coefficient of Resistance).

Comparing Samples 5-8, addition of iron enhances resistance value change.

Comparing Samples 9-14, addition of tin has an effect of reducing the TCR. Note that, in the present specification, a simple reference to “TCR” may mean an absolute value of the TCR.

In Comparative Examples 1 and 2, a little amount of iron is added to the copper-manganese-iron-silicon-based quaternary alloys in order to reduce the thermal electromotive forces with respect to copper. Note that, in the present specification, a simple reference to “thermal electromotive force with respect to copper” may mean an absolute value of the thermal electromotive force with respect to copper. From comparison between Comparative Examples 1 and 2 and other examples not including iron (in particular, Samples 1-3 and 9-14), addition of iron enhances resistance value changes (the decreased amounts of the resistance value) by the heat resistance test.

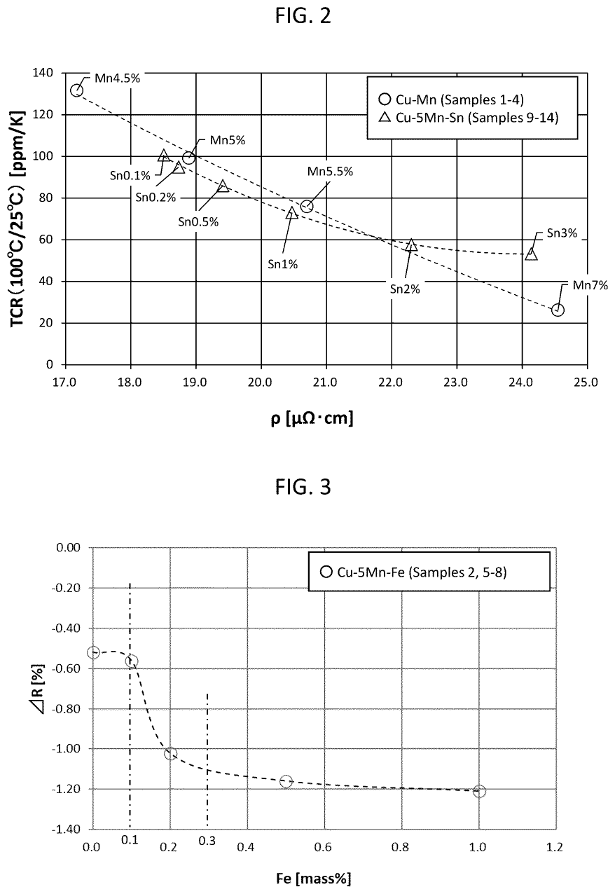

FIG. 2 is a graph showing relationship between volume resistivity (the horizontal axis, in μΩ·cm) and TCR (the vertical axis, in ppm/K) for Samples 1-4 and 9-14. Generally, adding another element in a copper-manganese-based alloy reduces the TCR and enhances the volume resistivity. Accordingly, upon evaluating an effect of reducing and improving a TCR property, the volume resistivity and the TCR have to be considered in combination. That is, the TCR can be evaluated to be worsened in a case where, with respect to the graph of the volume resistivity vs. TCR of copper-manganese-based alloys (FIG. 2), the TCR is greater for the same volume resistivity.

Comparing Samples 9-14, addition of a little amount of tin has an effect of reducing the TCR. However, if the added amount of tin exceeds 1%, decrement in the TCR becomes slightly mild, and if it exceeds 2%, a copper-manganese-based alloy without addition of tin would have a better TCR. Accordingly, it is preferable that the added amount of tin is 1% or less in order to improve the TCR.

FIG. 3 is a graph showing relationship between content of iron (the horizontal axis, in mass %) and resistance value change (the vertical axis, in %) for Samples 2 and 5-8. Comparing Samples 2, 5 and 6 in Table 1, addition of iron improves the thermal electromotive force with respect to copper. On the other hand, it enhances decrement in resistance value in the heat resistance test as shown in FIG. 3.

According to FIG. 3, a resistance alloy including 0.1-0.3 mass % of iron improves the thermal electromotive force with respect to copper while suppressing decrement in resistance value by the heat resistance test to be relatively small.

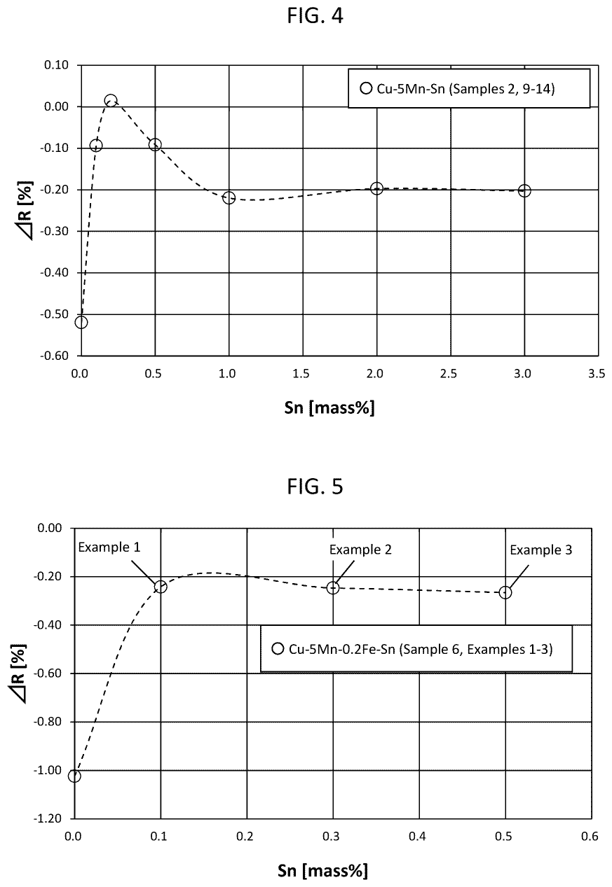

FIG. 4 is a graph showing relationship between content of tin (the horizontal axis, in mass %) and resistance value change (the vertical axis, in %) for Samples 2 and 9-14. In Sample 2 which does not include tin, the resistance value change is about −0.5%. By adding tin as in Samples 9-14, the resistance value changes were improved to about 0% to −0.3% and it was possible to reduce the resistance value changes.

FIG. 5 is a graph showing relationship between content of tin (the horizontal axis, in mass %) and the resistance value change (the vertical axis, in %) for Sample 6 and Examples 1-3. As described above, addition of iron is necessary in order to reduce the thermal electromotive force with respect to copper. Accordingly, cases (Examples 1-3) wherein tin is added to Cu-5Mn-0.2Fe (Sample 6) were tested. It is understood from Examples 1-3 that it was possible to reduce the decrements in resistance value in the heat resistance test by adding a little amount of tin.

As explained above, the copper alloy materials related to Examples 1-3 have a low volume resistivity (for example, about 20 μΩ·cm or less (more precisely, 21 μΩ·cm or less), or 15-25 μΩ·cm), a low TCR (for example, 100×10⁻⁶/K or less, or 150×10⁻⁶/K or less) and a small thermal electromotive force with respect to copper (for example, 1 μV/K or less).

The copper alloy materials related to Examples 1-3 are resistance alloys suitable for small and low-resistance shunt resistors and have low TCRs. By using such copper alloy materials, the current detection accuracy becomes good and space can be saved by downsizing so that it contributes to downsizing electronic devices.

All of Examples 1-3 include 5 mass % of manganese. Comparing them with Samples 1-4, it is considered that a low volume resistivity, a low TCR and a small thermal electromotive force with respect to copper can be maintained even if content of manganese is changed within a range of 4.5-5.5 mass %.

All of Examples 1-3 include 0.1-0.5 mass % of tin.

Thus, a copper-manganese-based copper alloy material including 4.5-5.5 mass % of manganese, 0.1-0.3 mass % of iron, 0.1-0.5 mass % of tin and a balance of copper has a low volume resistivity, a low TCR and a small thermal electromotive force with respect to copper.

Note that, as shown in Table 1 above, according to Examples 1-3, the volume resistivities are 15-25 μΩ·cm, the absolute values of the TCR are 150×10⁻⁶/K or less (more precisely, 50×10⁻⁶-150×10⁻⁶/K) and the thermal electromotive forces with respect to copper are 1 μV/K or less, and the resistance value changes in the heat resistance test of 175° C. for 3000 hours are −0.3% to 0%.

### Second Embodiment

A second embodiment is related to a shunt resistor for current detection. The shunt resistor related to the present embodiment is produced using the copper alloy material related to the first embodiment.

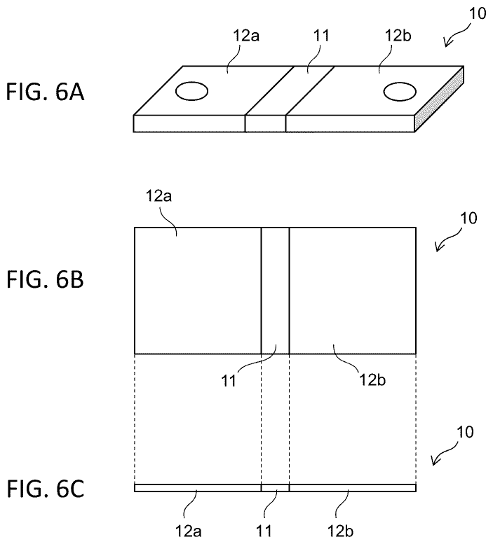

FIGS. 6A-6C. show an exemplary construction of the shunt resistor related to the second embodiment. FIG. 6A is a perspective view, FIG. 6B is a plan view and FIG. 6C is a side view.

The shunt resistor 10 shown in FIGS. 6A-6C has a structure wherein a piece-like resistive body 11 is produced by press working or the like and copper electrodes 12a, 12b are butt welded to opposite ends thereof.

The resistive body 11 and the electrodes 12a, 12b can be welded by EB (Electron Beam) welding, LB (Laser Beam) welding or the like. The shunt resistor 10 shown in FIGS. 6A-6C is a relatively large shunt resistor and can be produced one by one.

A material of the resistive body is formed by the copper-manganese-based copper alloy material described in the first embodiment. That is, the copper alloy material includes 4.5-5.5 mass % of manganese, 0.1-0.3 mass % of iron, 0.1-0.5 mass % of tin and a balance of copper.

The shunt resistor 10 can be small and can have a low resistance and it has a low TCR because the copper alloy material related to the first embodiment (Examples 1-3) described above is used. By using such shunt resistor 10, the current detection accuracy becomes good and space can be saved by downsizing so that it contributes to downsizing electronic devices.

What is claimed is:

1. A copper-manganese-based copper alloy material including 4.5-5.5 mass % of manganese, 0.1-0.3 mass % of iron, 0.1-0.5 mass % of tin, and a balance being copper.

2. The copper alloy material according to claim 1, wherein a volume resistivity is 15-25 μΩ·cm.

3. The copper alloy material according to claim 1, wherein an absolute value of TCR is 150×10⁻⁶/K or less.

4. The copper alloy material according to claim 1, wherein a thermal electromotive force with respect to copper is 1 μV/K or less.

5. The copper alloy material according to claim 1, wherein a resistance value change is −0.3% to 0% in a heat resistance test of 175° C. for 3000 hours.

6. A shunt resistor for current detection comprising a resistive body and an electrode, wherein:
the resistive body is formed by a copper-manganese-based copper alloy material; and
the copper alloy material includes 4.5-5.5 mass % of manganese, 0.1-0.3 mass % of iron, 0.1-0.5 mass % of tin, and a balance being copper.
